(19) United States
(12) Patent Application Publication
(10) Pub. No.: US 2010/0237394 A1
(43) Pub. Date: Sep. 23, 2010

(54) Semiconductor memory device

(76) Inventors: Jai-Kyun Park, Hwaesong-si (KR); Hyeong-Sun Hong, Seongnam-si (KR); Jong-Seop Lee, Suwon-si (KR); Yong-Il Kim, Hwaseong-si (KR); Yun-Sung Lee, Seongnam-si (KR); Nam-Jung Kang, Suwon-si (KR); Jae-Hoon Song, Anyang-si (KR); Gil-Sub Kim, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 12/659,735

(22) Filed: Mar. 19, 2010

(30) Foreign Application Priority Data
Mar. 20, 2009 (KR) 10-2009-0023925

(51) Int. Cl. H01L 27/108

(52) U.S. Cl. 257/296; 257/E27.084

(57) ABSTRACT

A semiconductor memory device includes unit active regions, word lines extending in a first direction over the unit active region, bit lines extending on the word lines in a second direction substantially perpendicularly to the first direction, first pad contacts in contact with central portions of the unit active regions, the first pad contacts being arranged between the word lines, direct contacts electrically connected between the first pad contacts and the bit lines, second pad contacts in contact with edge portions of the unit active regions, the second pad contacts being arranged between the word lines and between the bit lines, buried contacts electrically connected to the second pad contacts, and capacitors electrically connected to the buried contacts.

### BACKGROUND

1. Field

Example embodiments relate to a semiconductor memory device. More particularly, example embodiments relate to a semiconductor memory device with a layout capable of increasing a process margin.

2. Description of the Related Art

As semiconductor memory devices are highly integrated, a layout for arranging elements of a dynamic random access memory (DRAM) device in a small cell area may become important. Further, although the elements may be arranged in a small cell area, a sufficient process margin may be required to decrease process failures.

However, sizes of the elements and an interval between the elements in the DRAM cell may become narrower in accordance with the high integration of the semiconductor memory device. Thus, a short between contact plugs may be generated due to misalignment of the contact plugs. Moreover, a contact resistance may be greatly increased due to a small contact area between the contact plugs.

### SUMMARY

Embodiments are therefore directed to a semiconductor memory device that substantially overcomes one or more of the problems due to the limitations and disadvantages of the related art.

It is therefore a feature of an embodiment to provide a semiconductor memory device with a layout capable of ensuring a sufficient process margin.

At least one of the above and other features and advantages may be realized by providing a semiconductor memory device. The semiconductor memory device may include unit active region, word lines, bit lines, first pad contacts, direct contacts, second pad contacts, buried contacts and capacitors. The word lines may extend in a first direction over the unit active region. The word lines may have a first effective pitch. The bit lines may extend in a second direction substantially perpendicular to the first direction on the word lines. The bit lines may have the first effective pitch. The first pad contacts may make contact with central portions of the unit active regions. The first pad contacts may be arranged between the word lines. The direct contacts may be electrically connected between the first pad contacts and the bit lines. The second pad contacts may make contact with both edge portions of the unit active regions. The second pad contacts may be arranged between the word lines and the bit lines. The buried contacts may be electrically connected to the second pad contacts. The capacitors may be electrically connected to the buried contacts.

In some example embodiments, the two word lines spaced apart from each other may be arranged over each of the unit active regions.

In some example embodiments, the buried contacts may be aligned with the capacitors along a vertical straight line.

In some example embodiments, the capacitors may be spaced apart from each other by substantially the same interval along the first direction. Alternatively, the capacitors may be spaced apart from each other by substantially the same interval along the second direction.

In some example embodiments, the direct contacts may have lower surfaces aligned with upper surfaces of the first pad contacts.

In some example embodiments, cells may be arranged in the unit active region. The cells may have an open bit line structure. Each of the cells may include the word line, the bit line, and the capacitor.

In some example embodiments, the two word lines may cross an isolation region between the unit active regions along the first direction.

In some example embodiments, cells may be arranged in the unit active region. Each of the cells may include the word line, the bit line, and the capacitor. Each of the cells may have a square shape.

In some example embodiments, the unit active regions may make contact with s single first pad contact and two second pad contacts. The active regions may be inclined to the word lines.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a circuit diagram of a cell of a DRAM device in accordance with some example embodiments;

FIG. 2 illustrates a plan view of the DRAM device in FIG. 1;

FIG. 3 illustrates a cross-sectional view of the DRAM device in FIG. 2;

FIG. 4 illustrates a plan view of a cell of a DRAM device in accordance with some other example embodiments;

FIG. 5 illustrates a plan view of a cell of a DRAM device in accordance with some other example embodiments; and

FIG. 6 illustrates a plan view of a cell of a DRAM device in accordance with some other example embodiments.

### DETAILED DESCRIPTION

Korean Patent Application No. 10-2009-0023925, filed on Mar. 20, 2009, in the Korean Intellectual Property Office, and entitled: “Semiconductor Memory Device,” is incorporated by reference herein in its entirety.

Various example embodiments will be described more fully hereinafter with reference to the accompanying drawings, in which some example embodiments are shown. Example embodiments may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. In addition, it will also be understood that when an element or layer is referred to as being “between” two elements, it can be the only element between the two elements, or one or more intervening element may also be present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

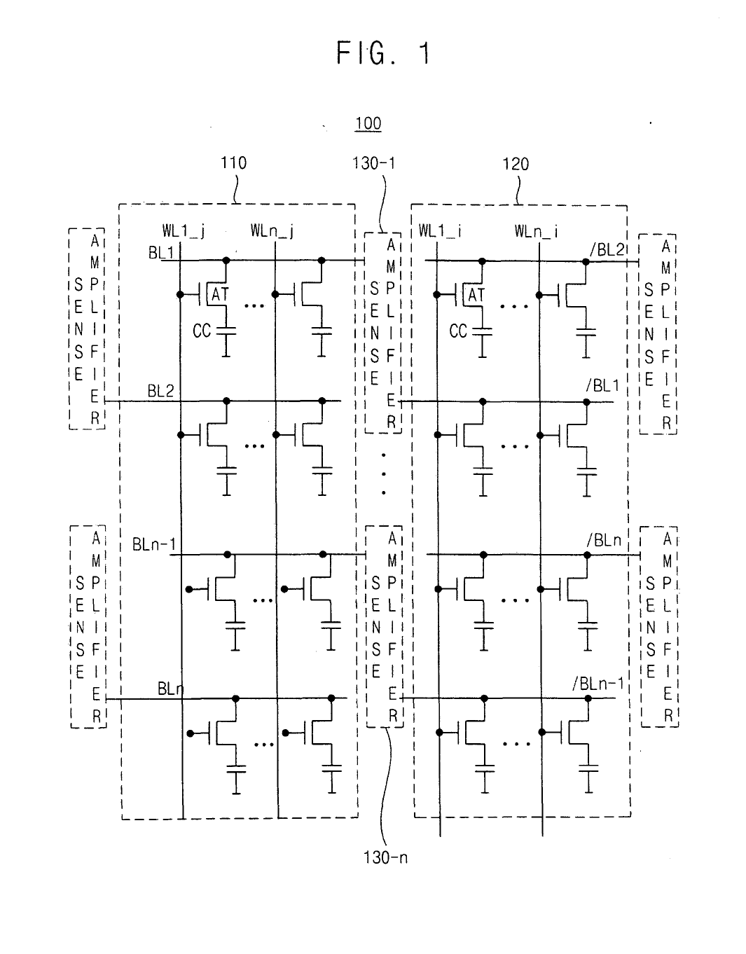

FIG. 1 illustrates a circuit diagram of a cell of a DRAM device in accordance with some example embodiments. It is noted that the cell of the DRAM of this example embodiment may be applied to other example embodiments illustrated later.

Referring to FIG. 1, a DRAM cell block may include a first memory block 110, a second memory block 120, and sense amplifiers 130-1˜130-n. Bit lines BL1˜BLn may be alternately arranged in the first memory block 110. Bit line bars BL1˜BLn may be alternately arranged in the second memory block 120. Each of the sense amplifiers 130-1˜130-n may be connected between odd bit lines of the bit lines BL1˜BLn and even bit line bars of the bit line bars /BL1˜/BLn to detect a voltage difference between a bit line BL and a corresponding bit line bar /BL.

Each of the memory blocks 110 and 120 may include memory cells. Each of the memory cells may include an access transistor AT and a cell capacitor CC at an intersection portion between the bit lines BL1˜BLn or the bit line bars /BL1˜/BLn and word lines WL1-j˜WLm-j, WL1-i˜WLm-1.

The DRAM cell of this example embodiment may have an open bit line structure, where the bit lines BL1˜BLn and the bit line bars /BL1˜/BLn may be spaced apart from each other toward both side directions of the sense amplifiers 130-1˜130-n, e.g., spaced apart horizontally. In the DRAM cell having the open bit line structure, when a selected single word line is operated, all of the cells connected to the selected word line and arranged along the bit lines BL1˜BLn may be operated. Further, a signal of a bit line corresponding to a selected cell by the sense amplifier may be compared with a signal of a bit line bar arranged opposite the sense amplifier to output data of the selected cell.

Although not depicted in drawings, a single word line in the DRAM cell having the open bit line structure may not cross an isolation region between unit active regions arranged along the bit line. That is, the single word line may cross the active regions arranged along a first direction. Alternatively, the word line may cross an isolation region between unit active regions arranged along a second direction substantially perpendicular to the first direction. Here, two word lines crossing the unit active region along the first direction may cross the single isolation region.

In contrast, when the DRAM cell has a folded bit line structure, i.e., when the bit line and the bit line bar are vertically arranged at an upper portion and a lower portion of the sense amplifier, the bit line and the bit line bar may be arranged in a single direction from the sense amplifier. Thus, when a selected single word line is operated, the cells may be alternately operated along the bit line direction. Therefore, when a word line crosses a unit active region, a next word line may cross an isolation region between the unit active regions.

In the DRAM cell having the folded bit line structure, the word lines crossing the isolation region may be larger in number than the word lines of the DRAM cell having the open bit line structure. Thus, contrary to the DRAM cell having the open bit line structure, the DRAM cell having the folded bit line structure may not be provided with a high integration degree.

A layout of the cell in the DRAM device in accordance with this example embodiment will be described hereinafter. The DRAM cell of this example embodiment may include two unit cells in a single active region. The unit active region may be surrounded by an isolation layer pattern. Thus, the unit active region may have an isolated island shape.

Two word lines serving as gate electrodes may be arranged spaced apart from each other in the unit active region. The word line may extend in the first direction. The word line may include a gate insulating layer and a gate electrode formed on the gate insulating layer. Impurities may be implanted into the active region between the word lines to form source/drain regions.

First pad contacts may be arranged at a central portion of the unit active region between the word lines. Second pad contacts may be arranged at an edge portion of the unit active region along side directions of the word lines.

Direct contacts may be formed on the first pad contacts, respectively. A bit line may make contact with upper surfaces of the direct contacts. The bit line may extend along the second direction.

In some example embodiments, the word line may have an effective pitch substantially the same as that of the bit line. The effective pitch may correspond to a pitch of the single word line or the single bit line. That is, the effective pitch may correspond to a minimum pitch of the bit lines or the word lines repeatedly arranged.

Buried contacts may be formed on upper surfaces of the second pad contacts. That is, the two buried contacts may be located in the unit active region.

A capacitor may be located on the upper surface of the buried contact. The capacitor may include a lower electrode aligned with the upper surface of the buried contact.

The buried contact and the lower electrode of the capacitor may have vertically protruded shapes from a semiconductor substrate. The buried contact and the lower electrode of the capacitor may be arranged in a serial arrangement. Therefore, a contact area between the buried contact and the lower electrode may be increased. As a result, a contact resistance between the buried contact and the lower electrode may be decreased. Further, because a misalignment margin may be increased when forming the buried contact and the capacitor, the buried contact and the lower electrode may not be opened, and/or a short between the buried contact and an adjacent lower electrode may be prevented.

In some example embodiments, the two unit cells may be arranged in the unit active region. Therefore, the single unit cell may include a half of the active region, the single word line, and the single buried contact.

In some example embodiments, the effective unit cell may have a square shape. The shape of the effective unit cell may correspond to a shape of the single unit cell. An area of the effective unit cell may correspond to an area of the single unit cell.

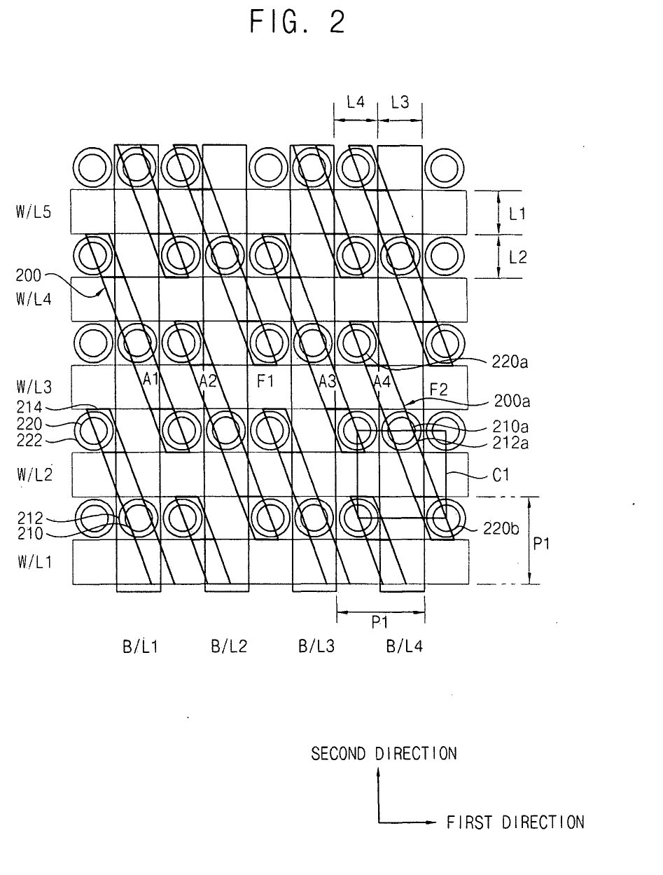

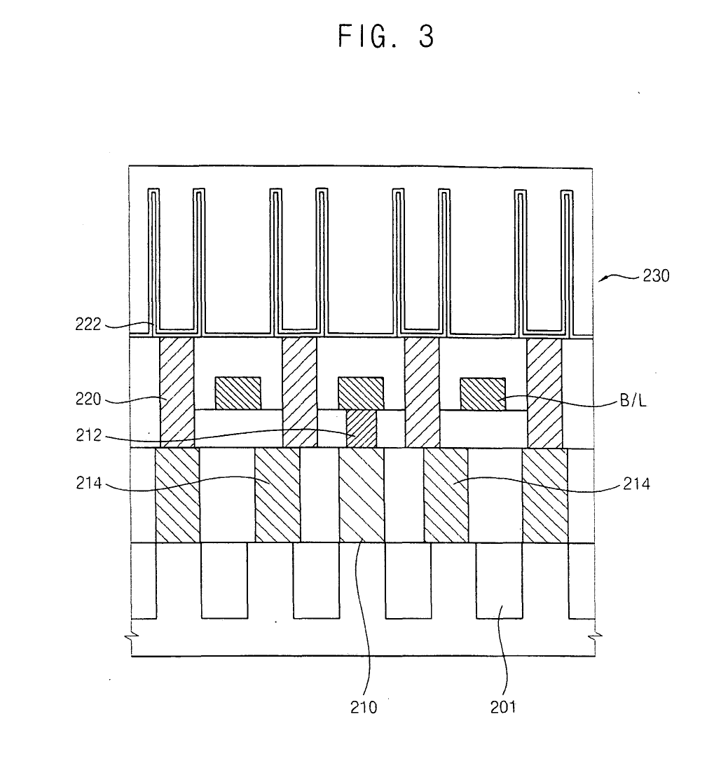

FIG. 2 illustrates a plan view of the DRAM device in FIG. 1. FIG. 3 illustrates a cross-sectional view of the DRAM device in FIG. 2.

Referring to FIG. 2, unit active regions 200 may be arranged slantly at an acute angle with respect to word lines W/L1˜W/L5. That is, the unit active regions 200 may not be perpendicular to the word lines W/L1˜W/L5. In some example embodiments, the unit active regions 200 may not be arranged in parallel to an extending direction of the word lines W/L1˜W/L5.

In some example embodiments, each of the unit active regions 200 may have an isolated shape. Other regions besides the unit active regions 200 may correspond to an isolation region.

The word lines W/L1˜W/L5 may extend in a first direction over the unit active regions 200. The word lines W/L1˜W/L5 may have a first effective pitch P1. The word lines W/L1˜W/L5 may serve as a gate structure of a transistor. For example, in some example embodiments, second and third word lines W/L2 and W/L3 may be arranged to be spaced apart from each other over a plurality of unit active regions 200, e.g., over each of the unit active regions 200.

Bit lines B/L1˜B/L4 may be arranged over the word lines W/L1˜W/L5 along a second direction substantially perpendicular to the first direction. The bit lines B/L1˜B/L4 may be spaced apart from each other. The bit lines B/L1˜B/L4 may have the first effective pitch P1.

In some example embodiments, the word lines W/L1˜W/L5 may have a width L1 substantially the same as an interval L2 between adjacent word lines W/L1˜W/L5. Each of the width L1 and the interval L2 may be about a half of the first effective pitch P1. Further, the bit lines B/L1˜B/L4 may have a width L3 substantially the same as an interval L4 between adjacent bit lines B/L1˜B/L4. Alternatively, the width L1 of the word lines W/L1˜W/L5 may be different from the interval L2 between the word lines W/L1˜W/L5. Further, the width L3 of the bit lines B/L1˜B/L4 may be different from the interval L4 between the bit lines B/L1˜B/L4.

First pad contacts 210 may be arranged at center portions of the unit active regions 200. The first pad contacts 210 may make contact with upper surfaces of the unit active regions 200. In detail, the first pad contacts 210 may be positioned on, e.g., directly on, the active regions 200 at intersection portions of gaps between adjacent word lines W/L1˜W/L5 and the bit lines B/L1˜B/L4. That is, each first pad contact 210 may be positioned in a gap between adjacent word lines W/L1˜W/L5, and may overlap one of the bit lines B/L1˜B/L4. In some example embodiments, the first pad contacts 210 may be alternatively arranged at the intersected portions of the gaps between the word lines W/L1˜W/L5 and the bit lines B/L1˜B/L4. For example, as illustrated in FIG. 2, two first pad contacts 210 may be arranged in a gap between word lines W/L1 and W/L2 to overlap the odd bit lines B/L1 and B/L3, respectively. In another example, two first pad contacts 210 may be arranged in a gap between the word lines W/L2 and W/L3 to overlap the even bit lines B/L2 and B/L4, respectively.

Direct contacts 212 may be arranged on upper surfaces of the first pad contacts 210. The bit lines B/L1˜B/L4 may make contact with upper surfaces of the direct contacts 212.

Referring to FIG. 3, the direct contacts 212 may have bottom surfaces substantially coplanar with the upper surfaces of the first pad contacts 210, e.g., the direct contacts 212 may be directly on the first pad contacts 210. That is, the first pad contacts 210 and the direct contacts 212 may extend upwardly, so that a contact area between the direct contacts 212 and the first pad contacts 210 may be increased. Further, the direct contacts 212 may have upper surfaces in, e.g., direct, contact with the bit lines B/L1˜B/L4, so that a contact area between the direct contacts 212 and the bit lines B/L1˜B/L4 may be enlarged. Alternatively, the first pad contacts 210, the direct contacts 212, and the bit lines B/L1˜B/L4 may not make contact with each other.

Second pad contacts 214 may be arranged at edge portions of the unit active regions 200. The second pad contacts 214 may make contact with upper surfaces of the unit active regions 200. In detail, the second pad contacts 214 may be positioned on the active regions 200 at intersected portions of gaps between the word lines W/L1˜W/L5 and the unit active regions 200. Further, the second pad contacts 214 may be arranged at intersected portions of gaps between the word lines W/L1˜W/L5 and gaps between the bit lines B/L1˜B/L4. That is, each second pad contact 214 may be positioned in a gap between adjacent word lines W/L1˜W/L5, and may overlap a portion of the unit active region 200 and one of the bit lines B/L1˜B/L4. In some example embodiments, one first contact pad 210 may be positioned between two second pad contacts 214 in a same unit active region 200. In some example embodiments, one first contact pad 210 may be positioned between two second pad contacts 214, i.e., of different unit active regions 200, along the first direction. For example, as illustrated in FIG. 2, two second pad contacts 214 may be arranged in a gap between word lines W/L1 and W/L2 to overlap a gap between bit lines B/L2 and B/L3 and a gap between bit lines B/L3 and B/L4, respectively, such that a first contact 210 may be therebetween. For example, a shape of the second contact gaps 214 may be substantially the same as edges of the active regions 200, so the second contact pads 214 and edges of the active regions 200 may completely overlap each other.

Buried contacts 220 may be arranged on, e.g., directly on, the second pad contacts 214. Two buried contacts 220 may be arranged in a single unit active region 200, e.g., one buried contact 220 may be arranged in each edge of the unit active region 200 to overlap a respective second contact pad 214. The buried contacts 220 may be located at intersected portions of gaps between the word lines W/L1˜W/L5 and gaps between the bit lines B/L1˜B/L4, e.g., a buried contact 220 may be completely enclosed within a gap defined by two adjacent word lines and two respective adjacent bit lines. Thus, the buried contacts 220 may be slightly offset from the second pad contacts 214.

A capacitor 230 may be formed on the upper surfaces of the buried contacts 220. The capacitor 230 may include a lower electrode 222 making contact with the upper surfaces of the buried contacts 220.

In some example embodiments, the buried contacts 220 and the lower electrode 222 may extend upwardly. That is, the buried contacts 220 may be aligned with the capacitor 230 along a vertical straight line, i.e., a direction orthogonal to the first and second directions. Thus, a contact area between the buried contacts 220 and the lower electrode 222 may be enlarged, so that a contact resistance between the buried contacts 220 and the lower electrode 222 may be reduced.

The first pad contacts 210 may make contact with central portions of the unit active regions 200. The second pad contacts 214 may make contact with both edge portions of the unit active regions 200, respectively. The second pad contacts 214 may be slightly offset from the unit active regions 200.

Positions of the first pad contacts 210 and the buried contacts 220 may be determined in accordance with arrangements and shapes of the word lines W/L1˜W/L5 and the bit lines B/L1˜B/L4. Thus, the shape of the unit active regions 200 may be determined so as to constitute one first pad contact 210, two buried contacts 220, two word lines W/Ls, and one bit line B/L in one unit active region 200. Further, an angle between the unit active regions 200 and the word lines W/Ls may be determined. Positions of the second pad contacts 214 and the capacitor 230 may be determined in accordance with the position and the shape of the unit active regions 200.

For example, referring to FIG. 2, a unit active region 200a may be located adjacent to a first pad contact 210a along the second direction. Further, the unit active region 200a may overlap a first buried contact 220a, i.e., located above and to the left from the first pad contact 210a, and a second buried contact 220b, i.e., located below and to the right from the first pad contact 210a. In other example embodiments, the unit active region 200a may be located adjacent to the first pad contact 210a along a direction substantially opposite the second direction. The unit active regions 200 may overlap the first pad contacts 210 and the buried contacts 220 to determine the position and the shape of the unit active regions 200.

In some example embodiments, the word lines W/L1˜W/L5 may cross the isolation regions between the unit active regions 200 along the second direction. Two word lines of the word lines W/L1˜W/L5, which may cross the unit active regions 200, may cross a single isolation region.

For example, the third word line W/L3 may extend along the first direction over two unit active regions A1 and A2, i.e., arranged along a direction oriented at an acute angle with respect to the first direction, and over a single isolation region F1. The third word line W/L3 may then extend over two unit active regions A3 along the first direction and the single isolation region F2 along the second direction. Therefore, the DRAM device of this example embodiment may have the open bit line structure.

In some example embodiments, an effective unit cell C1 may have a rectangle shape having four sides that correspond to the width L1 of a single word line W/L, the interval L2 between the word lines W/Ls, the width L3 of a single bit line B/L, and the interval L4 between the bit lines B/Ls, e.g., a square shape where all these dimensions are equal. The effective unit cell C1 may correspond to an effective region where the unit cell may be formed. The cell may include a single bit line, a single word line, and a capacitor. Here, when a minimum width formed by a photolithography process is F, and pitches of the word line and the bit line are 2.45 F, a size of the effective unit cell may be about 6 F2.

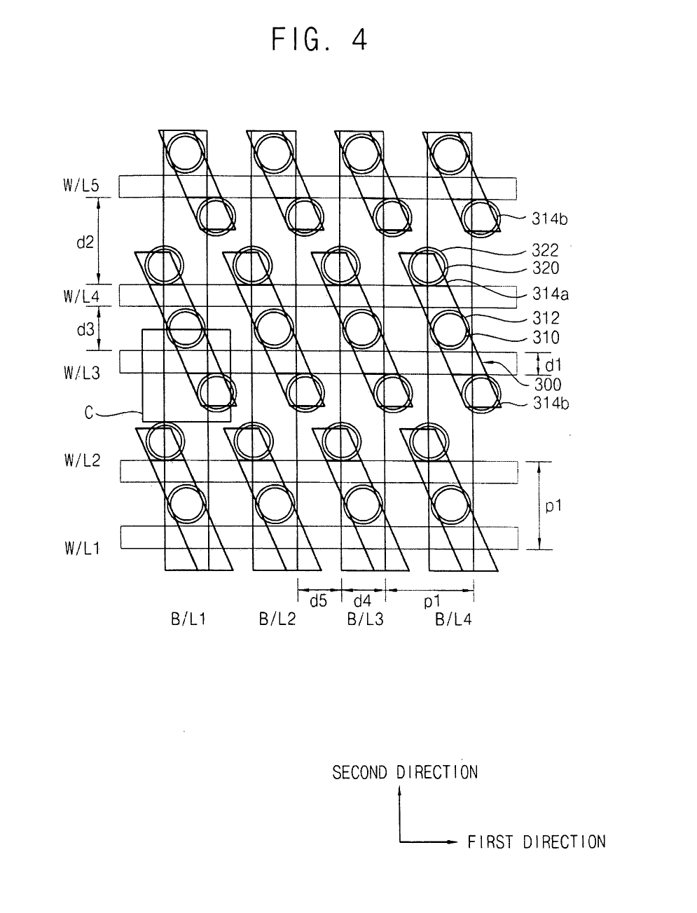

FIG. 4 illustrates a plan view of a cell of a DRAM device in accordance with some example embodiments.

Referring to FIG. 4, unit active regions 300 may be arranged slantly at an acute angle with respect to word lines W/L1˜W/L5. That is, the unit active regions 300 may not be perpendicular to the word lines W/L1′˜W/L5. In some example embodiments, the unit active regions 300 may not be parallely arranged along a first direction substantially in parallel to an extending direction of the word lines W/L1˜W/L5. In some example embodiments, each of the unit active regions 300 may have an isolated shape. Other regions besides the unit active regions 300 may correspond to an isolation region.

The word lines W/L1˜W/L5 may extend in the first direction. The word lines W/L1˜W/L5 may serve as a gate structure of a transistor. The word lines W/L1˜W/L5 may be positioned over the unit active regions 300. In some example embodiments, the two word lines W/L2 and W/L3 may be arranged spaced apart from each other over each of the unit active regions 300.

Bit lines B/L1˜B/L4 may have the first effective pitch P1, e.g., a constant pitch. For example, the bit line B/L1˜B/L4 may have a substantially same effective pitch as that of the word lines W/L1˜W/L5. The bit lines B/L1˜B/L4 may have a width different from that of the word lines W/L1˜W/L5, e.g., a width d4 of the bit lines may be wider than a width d1 of the word lines.

In some example embodiments, the pitch of the word lines may vary, so the word lines may have different intervals therebetween, e.g., the word lines W/L1˜W/L5 may have different first and second intervals d2 and d3 therebetween. However, the effective pitch in the word lines W/L1˜W/L5 may be the first effective pitch P1, i.e., a pitch of word lines having first contact pads 310, e.g., the second interval d3, therebetween. For example, the width d1 of the word lines W/L1˜W/L5 may be different from the first and second intervals d2 and d3 between the word lines W/L1˜W/L5. Further, the first and second intervals d2 and d3 between word lines W/L1˜W/L5 may be different from each other in accordance with positions of the word lines W/L1˜W/L5. That is, the first interval d2 between the word lines W/L1˜W/L5 crossing two columns of unit active regions 300 may be wider that the second interval d3 between the adjacent word lines W/Ls crossing a single column of unit active regions 300. It is noted that a “column” refers to an arrangement of a plurality of active regions 300 along a first direction, such that the active regions 300 are spaced apart from each other along the first direction.

In some example embodiments, the width d1 of the word lines W/L1˜W/L5 may be narrower than the second interval d3. For example, the first interval d2 may be equal the second interval d3 plus twice the width d1, such that the second interval d3 equals the pitch p1.

The bit lines B/L1˜B/L4 may be arranged over the word lines W/L1˜W/L5 along a second direction substantially perpendicular to the first direction. The bit lines B/L1˜B/L4 may be spaced apart from the word lines W/L1˜W/L5. In some example embodiments, the width d4 of the bit lines B/L1˜B/L4 and an interval d5 between the bit lines B/L1˜B/L4 may be different from the width d1 of the word lines W/L1˜W/L5. The width d4 of the bit lines B/L1˜B/L4 may be substantially the same as the interval d5 between the bit lines B/L1˜B/L4. For example, each of the width d4 of the bit lines B/L1˜B/L4 and the interval d5 between the bit lines B/L1˜B/L4 may equal the second interval d3.

First pad contacts 310 may be arranged at intersected portions of gaps between the word lines W/L1˜W/L5 and the bit lines B/L1˜B/L4. The first pad contacts 310 may make contact with upper central surfaces of the unit active regions 300. In some example embodiments, the first pad contacts 310 may be arranged at all of the intersected portions of the gaps between the word lines W/L1˜W/L5 and the bit lines B/L1˜B/L4.

Direct contacts 312 may be arranged on upper surfaces of the first pad contacts 310. The bit lines B/L1˜B/L4 may make contact with upper surfaces of the direct contacts 312.

Second pad contacts 314 may be arranged at edge portions, e.g., both edge portions, of the unit active regions 300 intersected with gaps between the word lines W/L1˜W/L5. Further, the second pad contacts 314 may be partially arranged at intersected portions of the gaps between the word lines W/L1˜W/L5 and gaps between the bit lines B/L1˜B/L4.

In some example embodiments, two second pad contacts 314 on each unit active region 300, i.e., second pad contacts 314a and 314b within a same unit active region 300, may be arranged to have the second interval d3 therebetween, e.g., along each column. In order to provide a space for the two second pad contacts 314a and 314b, the second interval d3 may be wider than the first interval d2.

In some example embodiments, the two second pad contacts 314a and 314b may be spaced apart from each other by substantially the same interval along the first direction, e.g., a plurality of pad contacts 314a within the column may be spaced apart from each other by a substantially same interval along the first direction as the pad contacts 314b in same columns. Further, due to the slanted orientation of the unit active regions 300 with respect to the word lines, the second pad contacts 314b along a second column may be interposed between the second pad contacts 314a along a first column. Thus, an interval between the second pad contacts 314a along the first column and the second pad contacts 314b along the second column may be widened to the maximum to ensure a sufficient process margin.

Buried contacts 320 may be arranged on the second pad contacts 314. In some example embodiments, because the buried contacts 320 may make contact with capacitors, it may be required to arrange the buried contacts 320 to provide the capacitors with sufficient intervals therebetween. Thus, the buried contacts 320 may be aligned with the upper surfaces of the second pad contacts 314a and 314b. Alternatively, the buried contacts 320 may be slightly offset from the second pad contacts 314a and 314b to partially contact the buried contacts 320 with the upper surfaces of the second pad contacts 314a and 314b.

The capacitor may be formed on the upper surfaces of the buried contacts 320. The capacitor may include a lower electrode 322 making contact with the upper surfaces of the buried contacts 320. Thus, a contact resistance between the buried contacts 320 and the lower electrode 322 may be reduced. Further, a contact alignment margin between the buried contacts 320 and the lower electrode 322 may be increased.

The first pad contacts 310 may make contact with central portions of the unit active regions 300. The second pad contacts 314a and 314b may make contact with both edge portions of the unit active regions 300, respectively.

Positions of the first pad contacts 310 and the second pad contacts 314a and 314b may be determined in accordance with arrangements and shapes of the word lines W/L1˜W/L5 and the bit lines B/L1˜B/L4 to widen the intervals between the first pad contacts 310 and the second pad contacts 314a and 314b. Thus, the shape of the unit active regions 300 may be determined so as to include one first pad contact 310, two second pad contacts 314a and 314b, two word lines W/Ls, and one bit line B/L in the unit active region 300. Further, an angle between the unit active regions 300 and the word lines W/Ls may be determined in accordance with the arrangements of the first contact pads 310 and the second pad contacts 314a and 314b.

The first pad contact 310, the second pad contacts 314a and 314b, and the word lines W/L3 and W/L4 may be arranged in the unit active region 300. For example, one first pad contact 310 may make contact with the bit line B/L4 along the second direction, and two second pad contact 314a may be located adjacent to the first pad contact 310, e.g., approximately along the second direction, on a same unit active region 300. As illustrated in FIG. 4, one second pad contact 314a may be located above and to the left from the first pad contact 310, and one second pad contact 314b may be arranged adjacent to the first pad contact 310 along a direction substantially opposite to the second direction, i.e., below and to the right from the first pad contact 310. The word lines W/L3 and W/L4 may extend between the first pad contact 310 and each of the second pad contacts 314b and 314a, respectively.

In some example embodiments, the word lines W/L1˜W/L5 may not cross the isolation regions between the unit active regions 300 along the second direction. Therefore, the DRAM device of this example embodiment may have the open bit line structure.

In some example embodiments, the effective unit cell may have a square shape having four sides that may correspond to the effective pitches of the word lines and the effective pitches of the bit lines. Here, when a minimum width formed by a photolithography process is F, and pitches of the word line and the bit line may be 2.45 F, a size of the effective unit cell may be about 6 F2. However, because two second pad contacts 314 are located in a single gap between the word lines, e.g., two second pad contacts 314 of different unit active regions 300 of different columns positioned in the first interval d2 illustrated in FIG. 4, the interval between the capacitors, i.e., lower electrodes 322, may be slightly narrower than that between the capacitors in FIG. 2.

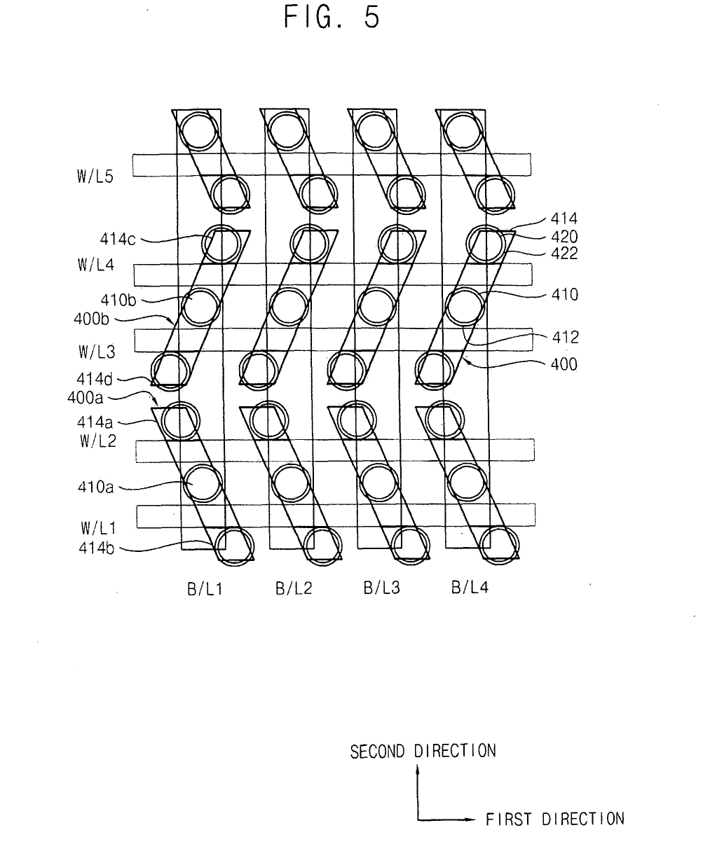

FIG. 5 illustrates a plan view of a cell of a DRAM device in accordance with some example embodiments. Here, the DRAM device of this example embodiment may include arrangements of word lines and bit lines substantially the same as those in FIG. 4 except for the active regions.

Referring to FIG. 5, unit active regions 400 may be arranged slantly at an acute angle with respect to word lines W/L1˜W/L5. That is, the unit active regions 400 may not be substantially perpendicular to the word lines W/L1˜W/L5. In some example embodiments, the unit active regions 400 may not be parallely arranged along a first direction substantially in parallel to an extending direction of the word lines W/L1˜W/L5. Further, the unit active regions 400 may include odd column active regions 400a and even column active regions 400b. The odd column active regions 400a and the even column active regions 400b may have different angles from each other.

Word lines W/L1˜W/L5 may have a shape and an arrangement substantially the same as those of the word lines in FIG. 4. Further, bit lines B/L1˜B/L4 may have a shape and an arrangement substantially the same as those of the bit lines in FIG. 4.

First pad contacts 410 may be arranged at intersected portions of gaps between the word lines W/L1˜W/L5 and the bit lines B/L1˜B/L4. In some example embodiments, the first pad contacts 410 may be located at all of the bit lines B/L1˜B/L4 overlapped with the gaps between the word lines W/L1˜W/L5. The first pad contacts 410 may make contact with central portions of the unit active regions 400.

Direct contacts 412 may be formed on upper surfaces of the first pad contacts 410, respectively. The direct contacts 412 may have upper surfaces making contact with bottom surfaces of the bit lines B/L1˜B/L4.

Second pad contacts 414 may be partially arranged at intersected portions of gaps between the word lines W/L1˜W/L5 and gaps between the bit lines B/L1˜B/L4. In some example embodiments, two second pad contacts 414 may be located at both sides of each of the first pad contacts 410 along approximately the second direction, i.e., within a same unit active region 400. The two second pad contacts 414 may be parallely arranged along the second direction at the gap between the word lines W/L1˜W/L5 having a second interval.

In some example embodiments, the second pad contacts 414 may be arranged by substantially the same interval along the first direction. An interval along the first direction between the second pad contacts 414 may be wider than along the second direction between the second pad contacts 414.

Buried contacts 420 may be formed on upper surfaces of the second pad contacts 414, respectively. That is, the two buried contacts 420 may be located in the single unit active region 400.

A capacitor may be formed on the upper surfaces of the buried contacts 420. The capacitor may include a lower electrode 422 making contact with the upper surfaces of the buried contacts 420.

The first pad contacts 410 may make contact with central portions of the unit active regions 400. The two second pad contacts 414 may make contact with both edge portions of the unit active regions 400, respectively. Here, positions of the first pad contacts 410 and the second pad contacts 414 may be determined in accordance with arrangements and shapes of the word lines W/L1˜W/L5 and the bit lines B/L1˜B/L4 to widen the intervals between the first pad contacts 410 and the second pad contacts 414. Thus, the shape of the unit active regions 400 may be determined so as to include one first pad contact 410, two second pad contacts 414, two word lines W/Ls, and two bit lines B/Ls in the unit active region 400.

In some example embodiments, an angle between an odd active region and an odd word line may be different from that between an even active region and an even word line.

For example, as illustrated in FIG. 5, a first pad contact 410a, second pad contacts 414a and 414b, and the word lines W/L1 and W/L2 may be arranged in the odd unit active region 400a. The first pad contact 410a may make contact with the bit line B/L1. The second pad contact 414a may be located adjacent to the first pad contact 410a along the second direction. The second pad contact 414a may be located left from the first pad contact 410a. The second pad contact 414b may be arranged adjacent to the first pad contact 410a along a direction substantially opposite to the second direction. The second pad contact 414b may be located right from the first pad contact 410a. The word lines W/L1 and W/L2 may extend between the first pad contact 410a and the second pad contacts 414a and 414b.

In another example, as illustrated in FIG. 5, a first pad contact 410b, second pad contacts 414c and 414d, and the word lines W/L3 and W/L4 may be arranged in the even unit active region 400b. The first pad contact 410b may make contact with the bit line B/L1. The second pad contact 414c may be located adjacent to the first pad contact 410b along the second direction. The second pad contact 414c may be located right from the first pad contact 410b. The second pad contact 414d may be arranged adjacent to the first pad contact 410b along a direction substantially opposite to the second direction. The second pad contact 414d may be located left from the first pad contact 410b. The word lines W/L3 and W/L4 may extend between the first pad contact 410b and the second pad contacts 414c and 414d.

In some example embodiments, the word lines may not cross the isolation regions between the unit active regions along the second direction. Thus, the DRAM device of this example embodiment may have an open bit line structure.

In some example embodiments, the effective unit cell may have a square shape having four sides that may correspond to the effective pitches of the word lines and the effective pitches of the bit lines. Here, when pitches of the word line and the bit line are 2.45 F, a size of the effective unit cell may be about 6 F2.

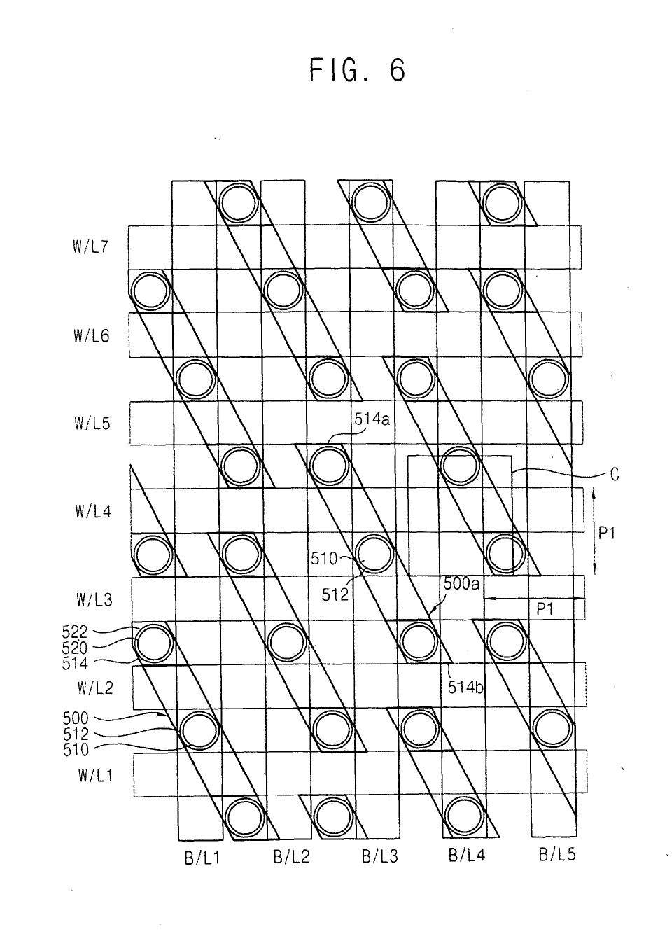

FIG. 6 illustrates a plan view of a cell of a DRAM device in accordance with some example embodiments.

Referring to FIG. 6, unit active regions 500 may be arranged slantly at an acute angle with respect to word lines W/L1˜W/L7. That is, the unit active regions 500 may not be substantially perpendicular to the word lines W/L1˜W/L7. In some example embodiments, the unit active regions 500 may not be parallely arranged along a first direction substantially in parallel to an extending direction of the word lines W/L1˜W/L7.

Word lines W/L1˜W/L7 may have a shape and an arrangement substantially the same as those of the word lines in FIG. 2. Further, bit lines B/L1˜B/L5 may have a shape and an arrangement substantially the same as those of the bit lines in FIG. 2. That is, the word lines W/L1˜W/L7 and the bit lines B/L1˜B/L5 may have substantially the same width, interval, and pitch P1.

First pad contacts 510 may be partially arranged at intersected portions of gaps between the word lines W/L1˜W/L7 and the bit lines B/L1˜B/L5. In some example embodiments, a single first pad contact 510 may be located at the intersected portion of a gap between the two word lines and the three bit lines along the first direction. For example, a single first pad contact 510 may be arranged at the intersected portion of a gap between the word lines W/L1 and W/L2 and the bit lines B/L1˜B/L5. The first pad contacts 510 may make contact with upper central portions of the unit active regions 500.

Direct contacts 512 may be formed on upper surfaces of the first pad contacts 510, respectively. The direct contacts 512 may have upper surfaces making contact with bottom surfaces of the bit lines B/L1˜B/L5.

Second pad contacts 514 may be partially arranged at intersected portions of gaps between the word lines W/L1˜W/L7 and gaps between the bit lines B/L1˜B/L5. In some example embodiments, the two second pad contacts 514 may be located at both sides of each of the first pad contacts 510 along the second direction. Further, the second pad contacts 514 may not be located at an intersected portion adjacent to the first pad contacts 510 along the first direction among the intersected portions the gaps between the word lines W/L1˜W/L7 and the bit lines B/L1˜B/L5.

Buried contacts 520 may be formed on upper surfaces of the second pad contacts 514, respectively. In some example embodiments, the buried contacts 520 may be aligned with the upper surfaces of the second pad contacts 514. Alternatively, the buried contacts 520 may be slightly offset from the upper surfaces of the second pad contacts 514 for allowing the buried contacts 520 to partially make contact with the upper surfaces of the second pad contacts 514.

A capacitor may be formed on the upper surfaces of the buried contacts 520. The capacitor may include a lower electrode 522 making contact with the upper surfaces of the buried contacts 520. Thus, the buried contacts 520 and the lower electrode 522 may have a low contact resistance and improved contact alignment margin.

The first pad contacts 510 may make contact with central portions of the unit active regions 500. The two second pad contacts 514 may make contact with both edge portions of the unit active regions 500, respectively.

In some example embodiments, positions of the first pad contacts 510 and the second pad contacts 514 may be determined in accordance with arrangements and shapes of the word lines W/L1˜W/L7 and the bit lines B/L1˜B/L5 to widen the intervals between the first pad contacts 510 and the second pad contacts 514. Thus, the shape of the unit active regions 500 may be determined so as to include one first pad contact 510, two second pad contacts 514, two word lines W/Ls, and one bit line B/L in the unit active region 500.

In some example embodiments, the first pad contact 510, second pad contacts 514a and 514b, and the word lines W/L3 and W/L4 may be arranged in the unit active region 500. The first pad contact 510 may make contact with the bit line B/L3. The second pad contact 514a may be located adjacent to the first pad contact 510 along the second direction. The second pad contact 514a may be located left from the first pad contact 510. The second pad contact 514b may be arranged adjacent to the first pad contact 510 along a direction substantially opposite to the second direction. The second pad contact 514b may be located right from the first pad contact 510. The word lines W/L3 and W/L4 may extend between the first pad contact 510 and the second pad contacts 514a and 514b.

In some example embodiments, the word lines W/L1˜W/L7 may cross the isolation regions between the unit active regions 500 along the second direction. That is, the two word lines among the word lines W/L1˜W/L7 that may cross the unit active regions 500 along the first direction may cross the single isolation region. Thus, the DRAM device of this example embodiment may have an open bit line structure.

In some example embodiments, the effective unit cell C may have a square shape. Here, when a minimum width formed by a photolithography process is F, and pitches of the word line and the bit line are 2.8 F, a size of the effective unit cell may be about 8 F2. However, because the buried contacts 520 are partially arranged at the gaps between the word lines and the bit lines, the DRAM device of this example embodiment may have an integration degree slightly lower than those of the DRAM devices in FIGS. 2, 4, and 5.

According to some example embodiments, the unit cells may be arranged in a small area, so that the semiconductor memory device may have a high integration degree. That is, unit active regions of the semiconductor memory device according to example embodiments may not be restricted within a specific shape, and the word lines and the bit lines may be arranged to maximize integration of the unit active regions. For example, the word lines and the bit lines may have substantially the same pitch, and the cells may have a square shape. Thus, because sizes of the cells are substantially the same, vertically stacked contacts may be accurately aligned. As a result, the contacts may have a low contact resistance, an accurate open structure, and a reliable electrical contact. Further, the semiconductor memory device may be manufactured by simple processes without additional processes. Furthermore, process failures may be suppressed during manufacturing of the semiconductor memory device. As a result, the semiconductor memory device may have high capacity and high reliability.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A semiconductor memory device, comprising:
unit active regions;
word lines extending in a first direction over the unit active region;
bit lines extending on the word lines in a second direction substantially perpendicularly to the first direction;
first pad contacts in contact with central portions of the unit active regions, the first pad contacts being arranged between the word lines;
direct contacts electrically connected between the first pad contacts and the bit lines;
second pad contacts in contact with edge portions of the unit active regions, the second pad contacts being arranged between the word lines and between the bit lines;
buried contacts electrically connected to the second pad contacts; and
capacitors electrically connected to the buried contacts.

2. The semiconductor memory device as claimed in claim 1, wherein two adjacent word lines spaced apart from each other are arranged over a plurality of unit active regions.

3. The semiconductor memory device as claimed in claim 1, wherein the buried contacts are aligned with the capacitors along a vertical straight line.

4. The semiconductor memory device as claimed in claim 3, wherein the capacitors are spaced apart from each other by substantially the same interval along the first direction.

5. The semiconductor memory device as claimed in claim 3, wherein the capacitors are spaced apart from each other by substantially the same interval along the second direction.

6. The semiconductor memory device as claimed in claim 1, wherein the direct contacts have lower surfaces aligned with upper surfaces of the first pad contacts.

7. The semiconductor memory device as claimed in claim 1, wherein cells are arranged in the unit active region, the cells having an open bit line structure, and each of the cells including one word line, one bit line, and one capacitor.

8. The semiconductor memory device as claimed in claim 1, wherein two adjacent word lines cross an isolation region between the unit active region along the first direction.

9. The semiconductor memory device as claimed in claim 1, wherein cells are arranged in the unit active region, each of cells including the word line, the bit line, and the capacitor, and each of the cells having a square shape.

10. The semiconductor memory device as claimed in claim 1, wherein each of the unit active regions contacts a single first pad contact and two second pad contacts, the active regions being inclined at an acute angle with respect to the word lines.

11. The semiconductor memory device as claimed in claim 1, wherein the bit lines and word lines have a same effective pitch.
